(19) United States
(12) Patent Application Publication
(10) Pub. No.: US 2026/0190660 A1
(43) Pub. Date: Jul. 2, 2026

(54) DISPLAY DEVICE AND MANUFACTURING METHOD FOR DISPLAY DEVICE

(71) Applicant: Samsung Display Co., Ltd., Yongin-si (KR)

(72) Inventors: JUNGYUN JO, Yongin-si (KR); JINGYU KIM, Yongin-si (KR)

(21) Appl. No.: 19/309,321

(22) Filed: Aug. 25, 2025

(30) Foreign Application Priority Data
Dec. 27, 2024 (KR) 10-2024-0198828

(51) Int. Cl. H10K 59/124; H10K 59/12

(52) U.S. Cl. CPC H10K 59/124; H10K 59/1201

(57) ABSTRACT

A display device includes a substrate, a light-emitting element layer, and a circuit element layer between the substrate and the light-emitting element layer and including a semiconductor layer including an active pattern, a first conductive layer above the semiconductor layer and including a first gate pattern overlapping the active pattern, a first insulating layer between the semiconductor layer and the first conductive layer, a second insulating layer above the first insulating layer and the first conductive layer, a third conductive layer above the semiconductor layer and the second insulating layer and including an input and output pattern contacting the active pattern, and an additional insulating layer between the active pattern and the first insulating layer and contacting the first insulating layer, wherein an interface between the first insulating layer and the additional insulating layer has an oxygen content that is greater than that of the first insulating layer.

### CROSS-REFERENCE TO RELATED APPLICATION

The present application claims priority to, and the benefit of, Korean Patent Application No. 10-2024-0198828, filed on Dec. 27, 2024, in the Korean Intellectual Property Office, the entire disclosure of which is incorporated herein by reference.

### BACKGROUND

### 1. Field

The present disclosure relates to a display device including pixels driven by a plurality of transistors, and a manufacturing method for the display device.

### 2. Description of the Related Art

A display device may show various images in a display screen to provide information to a user. The display device may be used in various electronic devices, such as a portable electronic device, for example a tablet PC, a smartphone, Personal Digital Assistant (PDA), Portable Multimedia Player (PMP), and/or a game console, a television, a personal computer, a laptop, or a kiosk. Furthermore, a display device is recently used in a wearable electronic device providing visual experience to a user by directly wearing glasses.

Development of various electronic devices using a display device and development of various functions gradually require a display device having high resolution. For example, a wearable electronic device may provide virtual reality or augmented reality to a user, but a display device having a low resolution may cause, for example, 3D motion sickness or result in lack of vividity. Such a display device having a high resolution involves integration of pixels. Accordingly, an integration method while maintaining display performance of pixels is desired.

### SUMMARY

An aspect of the present disclosure provides a display device having secured display performance of integrated pixels for implementation of high resolution, and a manufacturing method for the display device. In addition, an aspect of the present disclosure provides a display device with reduction or prevention of direct introduction of oxygen to an active layer or a conductive layer by having an additional insulating layer between an active layer and an insulating layer, or between a conductive layer and an insulating layer, in the manufacturing method of a display device, and a manufacturing method of the display device.

A display device according to one or more embodiments of the present disclosure includes a substrate, a light-emitting element layer above the substrate, and including a light-emitting material, and a circuit element layer between the substrate and the light-emitting element layer, and including a semiconductor layer above the substrate, and including an active pattern, a first conductive layer above the semiconductor layer, and including a first gate pattern overlapping the active pattern, a first insulating layer between the semiconductor layer and the first conductive layer, a second insulating layer above the first insulating layer and the first conductive layer, a third conductive layer above the semiconductor layer and the second insulating layer, and including an input and output pattern penetrating the first insulating layer and the second insulating layer to contact the active pattern, and an additional insulating layer between the active pattern and the first insulating layer, and contacting the first insulating layer, and wherein an interface between the first insulating layer and the additional insulating layer has an oxygen content that is greater than that of the first insulating layer.

An edge of the additional insulating layer and an edge of the semiconductor layer may be aligned.

The semiconductor layer may include polysilicon.

The additional insulating layer may include a same material as the first insulating layer.

The first insulating layer and the additional insulating layer may include silicon oxide.

The second insulating layer may include silicon nitride.

The circuit element layer may further include another additional insulating layer between the first gate pattern and the second insulating layer, and contacting the second insulating layer, wherein an interface between the second insulating layer and the another additional insulating layer has an oxygen content that is greater than that of the another additional insulating layer.

An edge of the another additional insulating layer and an edge of the first gate pattern may be aligned.

The another additional insulating layer may include a same material as the second insulating layer.

The second insulating layer and the another additional insulating layer may include silicon oxide.

The circuit element layer may further include a second conductive layer above the second insulating layer, and including a third gate pattern, a third insulating layer above the second insulating layer and the third conductive layer, and a fifth additional insulating layer between the third gate pattern and the third insulating layer and contacting the third insulating layer, wherein an interface between the third insulating layer and the fifth additional insulating layer has an oxygen content that is greater than that of the fifth additional insulating layer.

An edge of the fifth additional insulating layer and an edge of the third gate pattern may be aligned.

The third insulating layer and the fifth additional insulating layer may include silicon oxide.

A manufacturing method for a display device according to one or more embodiments of the present disclosure may include forming a semiconductor layer including an active pattern corresponding to a transistor above a substrate by forming an additional insulating layer above the semiconductor layer forming a coating layer above the additional insulating layer, etching the semiconductor layer, the additional insulating layer, and the coating layer to form the active pattern, and removing the coating layer, forming a first insulating layer above the semiconductor layer, forming a first conductive layer including a gate pattern above the first insulating layer and overlapping the active pattern, forming a second insulating layer above the first insulating layer and the first conductive layer, and forming a third conductive layer including an input and output pattern penetrating the first insulating layer and the second insulating layer to contact the active pattern.

The removing the coating layer may include supplying oxygen gas to remove the coating layer.

The coating layer may include amorphous carbon.

The forming the active pattern may further include applying a photoresistor, and etching the photoresistor with a mask patterned to have a shape corresponding to the active pattern.

The forming the first conductive layer may further include forming another additional insulating layer above the gate pattern, forming another coating layer above the another additional insulating layer, etching the first conductive layer, the another additional insulating layer, and the another coating layer to form the gate pattern, and removing the another coating layer.

An electronic device according to one or more embodiments of the present disclosure may include a display device for outputting image information, a processor configured to control the display device, a memory configured to store data for operation of the display device or the processor, and a power conversion module configured to generate or supply power, wherein the display device includes a substrate, a light-emitting element layer above the substrate, and including a light-emitting material, and a circuit element layer between the substrate and the light-emitting element layer, and including a semiconductor layer above the substrate, and including an active pattern, a first conductive layer above the semiconductor layer, and including a gate pattern overlapping the active pattern, a first insulating layer between the semiconductor layer and the first conductive layer, a second insulating layer above the first insulating layer and the first conductive layer, a third conductive layer above the semiconductor layer and the second insulating layer, and including an input and output pattern penetrating the first insulating layer and the second insulating layer to contact the active pattern, and an additional insulating layer between the active pattern and the first insulating layer, and contacting the first insulating layer, and wherein an interface between the first insulating layer and the additional insulating layer has an oxygen content that is greater than that of the first insulating layer.

An edge of the additional insulating layer and an edge of the semiconductor layer may be aligned to have a same pattern in plan view.

According to one or more embodiments of the present disclosure, an additional insulating layer is located between an active layer corresponding to a transistor region and an insulating layer to suppress a change of a device property due to introduction of oxygen and improve a lifespan or yield. Therefore, display performance of a transistor may be improved.

In addition, according to one or more embodiments of the present disclosure, an additional insulating layer is located between a gate pattern layer corresponding to a transistor region and an insulating layer to suppress a decrease in metal conductivity due to introduction of oxygen, and to improve a lifespan or yield. Therefore, display performance of a transistor may be improved.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic plan view of a display device according to one or more embodiments of the present disclosure;

FIG. 2 is an equivalent circuit diagram of the pixel shown in FIG. 1;

FIG. 3 is a timing diagram illustrating an operation of the pixel shown in FIG. 2;

FIG. 4 is a cross-sectional view of the pixel shown in FIG. 1;

FIG. 5 is a cross-sectional view illustrating an ordinary circuit element layer;

FIG. 6 is a cross-sectional view illustrating a circuit element layer according to one or more embodiments of the present disclosure;

FIGS. 7A through 7M are illustrations of a manufacturing method for a circuit element layer according to one or more embodiments of the present disclosure;

FIG. 8 is a cross-sectional view of a circuit element layer according to one or more embodiments of the present disclosure;

FIG. 9 is a cross-sectional view of a circuit element layer according to one or more embodiments of the present disclosure;

FIG. 10 is a block diagram of an electronic device according to one or more embodiments; and

FIG. 11 are schematic illustrations of an electronic device according to various embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer, or section described below could be termed a second element, component, region, layer, or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.” Furthermore, the expression “being the same” may mean “being substantially the same.” In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Hereinafter, a first direction through a third direction DR1 through DR3 may be defined to describe a display device according to one or more embodiments of the present disclosure. A display device may include a display panel, and the display panel may include pixels on a plane defined by a first direction DR1 and a second direction DR2 (e.g., in plan view). A third direction DR3 may be defined as a thickness direction of a display device, and the first direction through the third direction DR1 through DR3 may be orthogonal to one another.

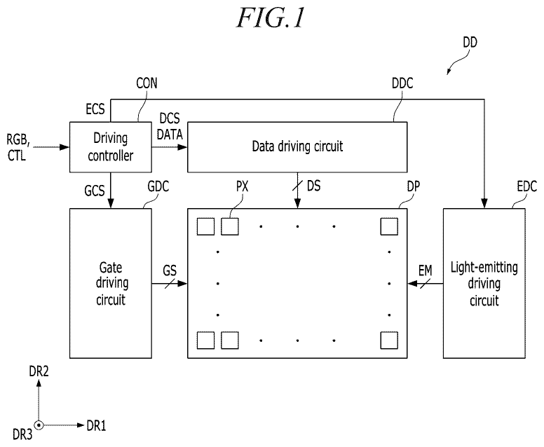

FIG. 1 is a schematic plan view of a display device according to one or more embodiments. Referring to FIG. 1, a display device DD may include a display panel DP, a gate driver (e.g., gate-driving circuit) GDC, a light emission driver (e.g., light-emitting-driving circuit) EDC, a data driver (e.g., data-driving circuit) DDC, and a driving controller CON. The display device may not be limited to what is illustrated in FIG. 1 and further include additional elements. For example, the display device DD may further include, for example, a voltage generator configured to generate voltages suitable for elements including the display panel DP.

The driving controller CON may be configured to receive an image signal RGB and a control signal CTRL. For example, the image signal RGB and the control signal CTRL may be provided from an application processor. The image signal RGB may be understood as a graphic source of an image to be shown in the display panel DP. The control signal CTRL may include a synchronization signal for synchronization for outputting an image at a precise position of the display panel DP. Such a synchronization signal may include a vertical synchronization signal for distinguishment of a frame, a horizontal synchronization signal for distinguishment of a row, and a data enable signal for distinguishment of an output section of image data.

The driving controller CON may be configured to generate an image data signal DATA converted from a data format of an image signal RGB to match with an interface specification of the data driver DDC. The driving controller CON may be configured to generate a gate control signal GCS configured to control a gate driver GDC based on a control signal CTRL, a driving control signal ECS configured to control the light emission driver EDC, and a data control signal DCS configured to control a data driver DDC.

The display panel DP may include pixels PX 2-dimensionally arranged on a plane defined by a first direction DR1 and a second direction DR2. The display panel DP may be electrically connected to a gate driver GDC through gate lines, and may be electrically connected to a light emission driver EDC through light-emitting control lines. The gate lines and the light-emitting control lines may extend in the first direction DR1. The display panel DP may be electrically connected to a data driver DDC through data lines. The data lines may extend in the second direction DR2.

The data driver DDC may be configured to receive a data control signal DCS and an image data signal DATA from the driving controller CON. The data driver DDC may be configured to analogously convert the image data signal DATA, which is a digital signal, to data signals DS. The data signals DS may be converted to correspond to a gradation value of an image data signal DATA. The data driver DDC may be configured to output the converted data signals DS to pixels PX through a plurality of data lines.

The gate driver GDC may be configured to receive a gate control signal GCS from the driving controller CON. The gate driver GDC may output gate signals GS to gate lines based on the gate control signal GCS. The gate driver GDC may be configured to successively activate a plurality of pixels PX by a row through the gate signals GS. Here, activation refers to a circumstance that data signals DS can be input to the plurality of pixels PX through data lines.

The light emission driver EDC may be configured to receive a light-emitting driving control signal ECS from the driving controller CON. The light emission driver EDC may be configured to output light-emitting control signals EM from light-emitting control lines based on the light-emitting driving control signal ECS. The light emission driver ECS may be configured to successively make the plurality of pixels PX to emit light through light-emission control signals EM.

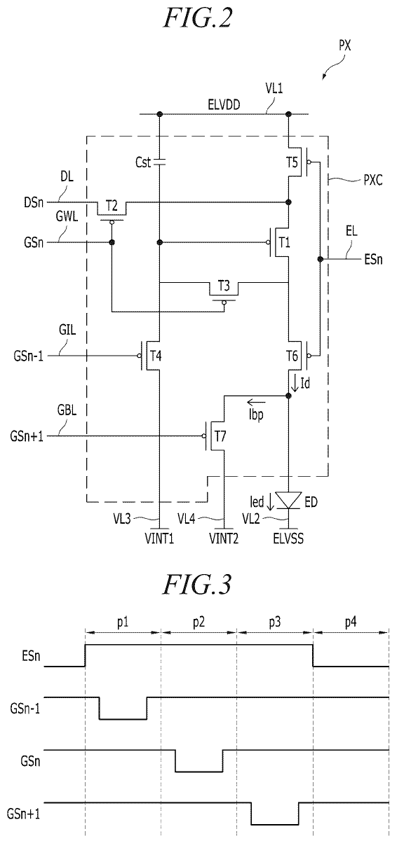

FIG. 2 is an equivalent circuit diagram of the pixel shown in FIG. 1. Referring to FIG. 2, the pixel PX may be electrically connected to a data line DL, gate lines GWL, GIL, and GBL (hereinafter, referred as a first gate line GIL, a second gate line GWL, and a third gate line GBL), and light-emitting control lines EL. The pixel PX may correspond to each of the plurality of pixels PX shown in FIG. 1.

The pixel PX may be configured to receive a first driving voltage ELVDD, a second driving voltage ELVSS, a first initialization voltage VINT1, and a second initialization voltage VINT2. In one or more embodiments, the first driving voltage ELVDD, a second driving voltage ELVSS, a first initialization voltage VINT1, and a second initialization voltage VINT2 may be provided by using voltage generated from, for example, a power control circuit of a display device DD.

The pixel PX may include a pixel circuit unit PXC and a light-emitting element ED. The pixel circuit unit PXC may include a first transistor through a seventh transistor T1 through T7 and one capacitor Cst. The first through seventh transistors T1 through T7 may each be a P-type transistor having a low-temperature polycrystalline silicon (LTPS) semiconductor layer. However, the transistors are not limited to the above, and may be an N-type transistor having an oxide semiconductor as a semiconductor layer. In addition, unlike FIG. 2, at least one of the first through the seventh transistors T1 through T7 may be an N-type transistor, and the others may be P-type transistors. A circuit configuration of a pixel PX and a number of transistors according to the present disclosure are merely shown as an example, and may not be limited to what is illustrated in FIG. 2, and a configuration of a pixel PXC may be modified and implemented.

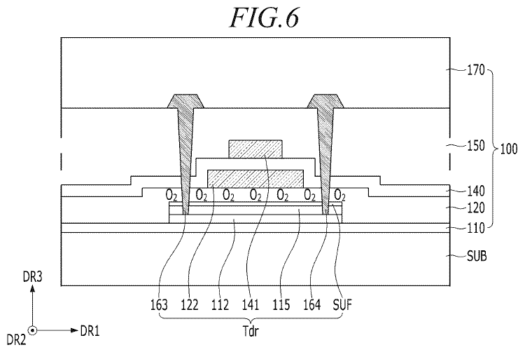

The first transistor T1 may be configured to provide a driving current Id based on a size of a data signal DSn to the light-emitting element ED. In consideration of the above, the first transistor T1 may be referred as a driving transistor Tdr described with respect to FIG. 4. The second transistor through the seventh transistor T2 through T7 may be configured to be turned on or off to allow the first transistor T1 to receive the data signal DSn, and may provide the driving current Id based on a size of the data signal DSn. To achieve the above, a gate electrode of the second transistor through the seventh transistor T2 through T7 may be connected to any one of a first gate line GIL, a second gate line GWL, a third gate line GBL, or a light-emission control line EL. In consideration of the above, the second transistor through the seventh transistor T2 through T7 may be referred as a switch transistor Tsw described with respect to FIG. 4.

The first transistor T1 may include a first electrode connected to a first driving voltage line VL1 through the fifth transistor T5, a second electrode electrically connected to an anode of the light-emitting element ED through the sixth transistor T6, and a gate electrode connected to an end of a capacitor Cst. The first transistor T1 may be configured to receive a data signal DSn provided through the data line DL based on a switching action of the second transistor T2 to provide a driving current Id to the light-emitting element ED.

The second transistor T2 may include a first electrode connected to the data line DL, a second electrode connected to the first electrode of the first transistor T1, and a gate electrode connected to the second gate line GWL. The second transistor T2 may be configured to be turned on based on a gate signal GSn (hereinafter, referred as a second gate signal) provided through the second gate line GWL to transfer the data signal DSn provided from the data line DL to the first electrode of the first transistor T1.

The third transistor T3 may include a first electrode connected to the gate electrode of the first transistor T1, a second electrode connected to the second electrode of the first transistor T1, and a gate electrode connected to the second gate line GWL. The third transistor T3 may be turned on based on the second gate signal GSn provided through the second gate line GWL to connect the gate electrode and the second electrode of the first transistor T1 to connect the first transistor T1 to the light-emitting element ED.

The fourth transistor T4 may include a first electrode connected to the gate electrode of the first transistor T1, a second electrode connected to a third voltage line VL3 to which the first initialization voltage VINT1 is provided, and a gate electrode connected to the first gate line GIL. The fourth transistor T4 may be turned on based on a gate signal GSn−1 (hereinafter, referred as a first gate signal) provided through the first gate line GIL to transfer the first initialization voltage VINT1 to the gate electrode of the first transistor T1 and perform initialization to initialize a voltage of the gate electrode of the first transistor T1.

The fifth transistor T5 may include a first electrode connected to the first driving voltage line VL1, a second electrode connected to the first electrode of the first transistor T1, and a gate electrode connected to the light-emission control line EL. The sixth transistor T6 may include a first electrode connected to the second electrode of the first transistor T1, a second electrode connected to an anode of the light-emitting element ED, and a gate electrode connected to the light-emission control line EL. The fifth transistor T5 and the sixth transistor T6 may be concurrently or substantially simultaneously turned on based on a light-emission signal ESn provided through the light-emission control line EL. The first driving voltage ELVDD applied through the turned on fifth transistor T5 may be compensated by the first transistor T1 and may be transferred to the light-emitting element ED.

The seventh transistor T7 may include a first electrode connected to a fourth voltage line VL4 through which a second initialization voltage VINT2 is transferred, a second electrode connected to the second electrode of the sixth transistor T6, and a gate electrode connected to the third gate line GBL. The seventh transistor T7 may be turned based on a gate signal GSn+1 (hereinafter, referred as a third gate signal) provided through the third gate line GBL. The second initialization voltage VINT2 applied through the turned on seventh transistor T7 may initialize the anode of the light-emitting element ED.

An end of the capacitor Cst may be connected to the gate electrode of the first transistor T1 as described above, and the other end may be connected to the first driving voltage line VL1. The cathode of the light-emitting element ED may be connected to the second driving voltage line VL2 through which the second driving voltage ELVSS is transferred.

The light-emitting element ED may include a light-emitting diode. The light-emitting diode may include a light-emitting material, such as an organic light-emitting material, an inorganic light-emitting material, a quantum dot, and/or a quantum rod. The light-emitting element ED may be configured to emit light based on a light-emitting current Ied.

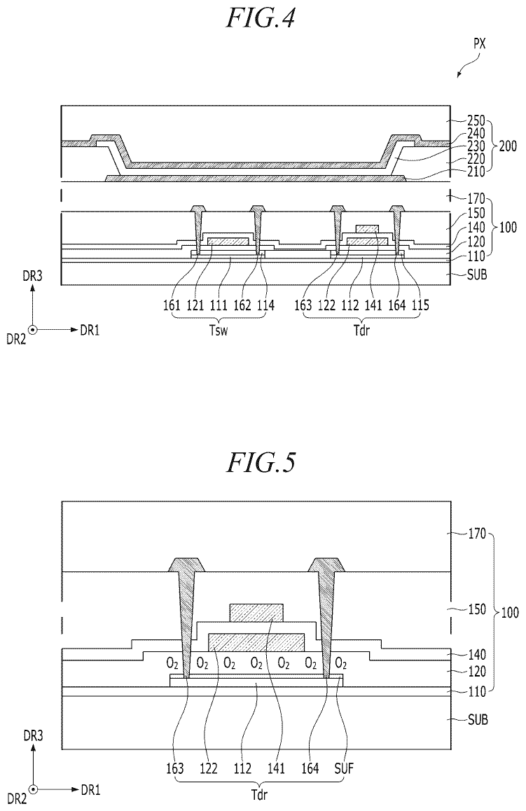

FIG. 3 is a timing diagram illustrating an operation of the pixel shown in FIG. 2. FIG. 3 is explained with reference to figure references of FIG. 2. Referring to FIG. 3, the pixel PX may be configured to operate in a first interval p1, a second interval p2, a third interval p3, and a fourth interval p4 for light-emitting operation.

In the first interval p1, a node for programming the pixel PX is initialized. During the first interval p1, a first gate signal GSn−1 of a low level is provided through a first gate line GIL. Based on the first gate signal GSn−1 of a low level, the fourth transistor T4 is turned on, the first initialization voltage VINT1 is transferred to the gate electrode of the first transistor T1 through the fourth transistor T4, and the first transistor T1 is initialized.

In the second interval p2, the pixel PXij becomes programmed. During the second interval p2, in case that the second gate signal GSn of a low level is provided through the first gate line GWL, the third transistor T3 is turned on. The first transistor T1 is diode-connected by the turned on third transistor T3, and becomes biased in a forward direction. In addition, the second transistor T2 is turned on by the second gate signal GSn of a low level. Accordingly, a compensation voltage DSn-Vth, which is the data signal DSn provided from the data line DL decreased by a threshold voltage Vth of the first transistor T1, is applied to the gate electrode of the first transistor T1. Such a gate electrode will be understood as a compensation voltage. Both ends of the capacitor Cst may be applied with the first driving voltage ELVDD and the compensation voltage, and charges corresponding to a difference between the ends may be stored in the capacitor Cst.

In the third interval p3, the anode of the light-emitting element ED becomes initialized. The seventh transistor T7 receives a third gate signal GSn+1 of a low level through the third gate line GBL and becomes turned on. Even in case that a reduced or minimum current of the first transistor T1 showing a black image flows as a driving current, a black image may not show properly if the light-emitting element ED emits light. Accordingly, the seventh transistor T7 may be configured to disperse a portion of the reduced or minimum current of the first transistor T1 to another path as a bypass current Ibp other than a current path towards the organic light-emitting diode. Light-emission current Ied of the light-emitting element ED, which is the driving current Id decreased by an amount of current of the bypass current Ibp, may have a reduced or minimum amount of current to the extent that a black image may be properly shown, and a contrast ratio may be improved.

In the fourth interval p4, the light-emitting element ED may be configured to emit light based on the programmed data signal DSn. The light-emission control signal ESn provided from the light-emission control line EL may be changed from a high level to a low level. The fifth and the sixth transistors T5 and T6 may be turned on by the light-emission control signal ESn of a low level. Accordingly, a driving current Id following a difference between a voltage of the gate electrode of the first transistor T1 and the first driving voltage ELVDD may be generated, and the driving current Id may be provided to the light-emitting element ED through the sixth transistor T6 to allow a light-emitting current Ied flow through the light-emitting element ED.

FIG. 4 is a cross-sectional view of the pixel shown in FIG. 1. Referring to FIG. 4, the pixel PX may include a substrate SUB, a circuit element layer 100, and a light-emitting element layer 200. For convenience of description, a cross-sectional view of the pixel PX is illustrated, but the pixels PX may be 2-dimensionally arranged as shown in FIG. 1, and the arrangement may be repeated in first direction DR1 as shown in FIG. 4. The pixels PX may be concurrently or substantially simultaneously manufactured while the circuit element layer 100 and the light-emitting element layer 200 shown in FIG. 4 are formed. Furthermore, a cross-section of the pixel PX shall be understood as simplified for convenience of description.

The substrate SUB may be formed of various materials, such as glass, metal, or plastic. For example, the substrate SUB may be a flexible substrate.

The circuit element layer 100 may be located on the substrate SUB. The circuit element layer 100 may correspond to the pixel circuit unit PXC shown in FIG. 2. The circuit element layer 100 may include a buffer layer 110, a semiconductor layer including a first active pattern 111 and a second active pattern 112, a first additional insulating layer 114 (e.g., an additional insulating layer, in the claims), a second additional insulating layer 115 (e.g., an additional insulating layer, in the claims), a first insulating layer 120, a first conductive layer including a first gate pattern 121 and a second gate pattern 122, a second insulating layer 140, a second conductive layer including a third gate pattern 141, a third insulating layer 150, a third conductive layer including a first input pattern 161, a first output pattern 162, a second input pattern 163, and a second output pattern 164 (e.g., an input and output pattern), and a planarization layer 170.

The circuit element layer 100 may have a switch transistor Tsw and a driving transistor Tdr formed along a lamination structure shown in FIG. 4. The driving transistor Tdr may correspond to the first transistor T1 shown in FIG. 2, and the switch transistor Tsw may correspond to any one of the second through the seventh transistors shown in FIG. 2. For convenience of description, it is illustrated in the cross-sectional view of FIG. 4 that one switch transistor Tsw and one driving transistor Tdr are present. However, it shall be understood as an example. A number of the switch transistor Tsw and the driving transistor Tdr shown in a plane defined by the first direction DR1 and the third direction DR3 may not be limited.

The buffer layer 110 may be located on the substrate SUB (as used herein, “located on” may mean “above”). The buffer layer 110 may be configured to reduce or prevent diffusion of an impurity ion on an upper surface of the substrate SUB, to reduce or prevent penetration of moisture or outside air, and to planarize a surface. For example, the buffer layer 110 may be formed of an inorganic material, such as silicon oxide, silicon nitride, aluminum oxide, aluminum nitride, titanium oxide, or titanium nitride, an organic material, such as polyimide, polyester, or acryl, or a lamination thereof.

The semiconductor layer including a first active pattern 111 and a second active pattern 112 may be located on the substrate SUB and the buffer layer 110. For example, the semiconductor layer may use an inorganic semiconductor, such as amorphous silicon or polysilicon, or an organic semiconductor. The first active pattern 111 may be configured to provide a signal input and output channel of the switch transistor Tsw, and the second active pattern 112 may be configured to provide a signal input and output channel of the driving transistor Tdr.

The first insulating layer 120 may be located on the first active pattern 111 and the second active pattern 112, and may cover the first active pattern 111 and the second active pattern 112. For example, the first insulating layer 120 may be formed of a laminate including silicon oxide, but the present disclosure is not limited thereto. The silicon oxide may have an excellent interface property with a silicon substrate and have a dielectric constant suitable to be used as a gate-insulating layer.

The first insulating layer 120 may function as a gate insulant of the switch transistor Tsw and the driving transistor Tdr.

The first conductive layer including a first gate pattern 121 and a second gate pattern 122 may be located on the first insulating layer 120. The first gate pattern 121 may be located to overlap with the first active pattern 111, and the second gate pattern 122 may be located to overlap with the second active pattern 112. The first gate pattern 121 may be a gate electrode of the switch transistor Tsw, and the second gate pattern 122 may be a gate electrode of the driving transistor Tdr. The first conductive layer may further include the gate lines and the light-emission control lines described above. For example, the gate lines or the light-emission control lines may be electrically connected to the first gate pattern 121 of a corresponding switch transistor Tsw among the second through the seventh transistors T2 through T7 shown in FIG. 2.

The first additional insulating layer 114 and the second additional insulating layer 115 may be located between the semiconductor layer including the first active pattern 111 and the second active pattern 112 and the first insulating layer 120. The first additional insulating layer 114 and the second additional insulating layer 115 may be configured to reduce or prevent direct introduction of oxygen to the semiconductor layer while the circuit element layer 100 is formed.

Edges of the first additional insulating layer 114 and the second additional insulating layer 115 may be aligned with edges of the first active pattern 111 and the second active pattern 112 in the semiconductor layer. Accordingly, the first additional insulating layer 114 and the second additional insulating layer 115 may respectively have a same planar pattern as the first active pattern 111 and the second active pattern 112. This is because during a manufacturing process, the first active pattern 111 overlapping with the first additional insulating layer 114 and the second active pattern 112 overlapping with the second additional insulating layer 115 are each concurrently or substantially simultaneously etched. A material of the first additional insulating layer 114 and the second additional insulating layer 115 may be the same material of the first insulating layer 120, which is an insulating layer above.

The second insulating layer 140 may cover the first conductive layer including a first gate pattern 121 and a second gate pattern 122. For example, the second insulating layer 140 may be formed of a laminate including silicon oxide or silicon nitride, but the present disclosure is not limited thereto. The second insulating layer 140 may function as a dielectric of the capacitor Cst described in FIG. 2.

The second conductive layer including a third gate pattern 141 may be located on the second insulating layer 140. The third gate pattern 141 may be located to overlap with the second gate pattern 122. The second gate pattern 122 and the third gate pattern 141 may function as the capacitor Cst described in FIG. 2. As the capacitor Cst is formed to overlap with a region corresponding to the driving transistor Tdr, miniaturization and integration of the pixel PX are possible, and resolution of the display device DD may be increased. However, the present disclosure is not limited thereto, and the third gate pattern 141 may be located not to overlap with the region corresponding to the driving transistor Tdr. The first, second, and third gate patterns 121, 122, and 141 may be a metallic material, such as aluminum, molybdenum, or chrome.

The third insulating layer 150 may be located on the second conductive layer including the second insulating layer 140 and the third gate pattern 141 to cover the second conductive layer. For example, the third insulating layer 150 may be formed of a laminate including silicon oxide or silicon nitride, but the present disclosure is not limited thereto. The third insulating layer 150 may have contact holes formed for formation of a first input pattern 161, a first output pattern 162, a second input pattern 163, and a second output pattern 164.

The third conductive layer including the first input pattern 161, the first output pattern 162, the second input pattern 163, and the second output pattern 164 may be located on the third insulating layer 150, and may contact the semiconductor layer through the described contact holes, respectively. The first input pattern 161 and the first output pattern 162 may penetrate through the first, second, and third insulating layers 120, 140, and 150 to contact the first active pattern 111. The second input pattern 163 and the second output pattern 164 may penetrate through the first, second, and third insulating layers 120, 140, and 150 to contact the second active pattern 112. The first input pattern 161 may be an input electrode of the switch transistor Tsw, the first output pattern 162 may be an output electrode of the switch transistor Tsw, the second input pattern 163 may be an input electrode of the driving transistor Tdr, and the second output pattern 164 may be an output electrode of the driving transistor Tdr.

The third conductive layer may further include the described data lines and a first driving line. For example, the data line may be electrically connected to the first input pattern 161 of the switch transistor Tsw corresponding to the second transistor T2. For example, the first driving line may be electrically connected to the third gate pattern 141. The first driving line may be located physically closer to the second input pattern 163 inputted with the driving current than the second output pattern 164 outputting the driving current.

The planarization layer 170 may be configured to provide a flat upper surface to planarize the light-emitting element layer 200. In the planarization layer 170, a film composed of an organic material or inorganic material may be formed as a single layer or multiple layers. In one or more embodiments, the planarization layer 170 may have a contact hole formed for electrical connection with the third conductive layer. A contact pattern formed in the contact hole may be configured to transfer the driving current provided from the circuit element layer 100 to the light-emitting element layer 200. The contact pattern may be located physically closer to the second output pattern 164 outputting the driving current than the second input pattern 163 inputted with the driving current.

The light-emitting element layer 200 may be located on a pixel device layer. The light-emitting element layer 200 may correspond to the light-emitting element ED shown in FIG. 2. The light-emitting element layer 200 may include a first electrode layer 210, a pixel-defining layer 220, a light-emitting layer 230, a second electrode layer 240, and an encapsulation layer 250. It shall be understood that a configuration of the light-emitting element layer 200 is simplified for convenience of description.

The first electrode layer 210 may be located on the planarization layer 170. The first electrode layer 210 may include a conductive oxide material, such as indium tin oxide (ITO), indium zinc oxide (IZO), zinc oxide (ZnO), indium oxide (In2O3), indium gallium oxide (IGO), or aluminum zinc oxide (AZO). The first electrode layer 210 may be an anode electrode of the light-emitting element ED.

The pixel-defining layer 220 may be located on the first electrode layer 210 (e.g., a portion of the first electrode layer 210) and the planarization layer 170. The pixel-defining layer 220 may have an opening part defined therein, and at least a portion of the first electrode layer 210 may be exposed through the opening part. The pixel-defining layer 220 may have a region defined by the opening part to correspond to one pixel. The pixel-defining layer 220 may have an exposed light-emitting region defined by non-light-emitting region and the opening part overlapping with the pixel-defining layer 220 in the display panel DP.

The light-emitting layer 230 may be located on the first electrode layer 210 and the pixel-defining layer 220. The light-emitting layer 230 may include a light-emitting material. For example, the light-emitting layer 230 may include an organic material including a fluorescent or phosphorescent material that may emit light, such as red, green, and/or blue. The light-emitting layer 230 may include a small molecule organic material or a polymer organic molecule. In one or more embodiments, the light-emitting element layer 200 may further include a hole control layer, such as a hole transport layer (HTL) and/or a hole injection layer (HIL), between the light-emitting layer 230 and the first electrode layer 210. In one or more embodiments, the light-emitting element layer 200 may further include an electron control layer, such as an electron transport layer (ETL) and/or an electron injection layer (EIL), between the light-emitting layer 230 and the second electrode layer 240.

The second electrode layer 240 may be located on the light-emitting layer 230. The second electrode layer 240 may be generally located on the plurality of pixels PX. The second electrode layer 240 may be a transmissive electrode or a reflective electrode. In one or more other embodiments, the second electrode layer 240 may a transparent or translucent electrode. The second electrode layer 240 may include a conductive oxide material, such as indium tin oxide (ITO), indium zinc oxide (IZO), zinc oxide (ZnO), indium oxide (In2O3), indium gallium oxide (IGO), or aluminum zinc oxide (AZO). The second electrode layer 240 may be a cathode electrode of the light-emitting diode ED.

The encapsulation layer 250 may be located on the second electrode layer 240. The encapsulation layer 250 may include at least one inorganic encapsulation layer and at least one organic encapsulation layer. The encapsulation layer 250 may be configured to protect the light-emitting element layer 200 from external moisture or contaminants.

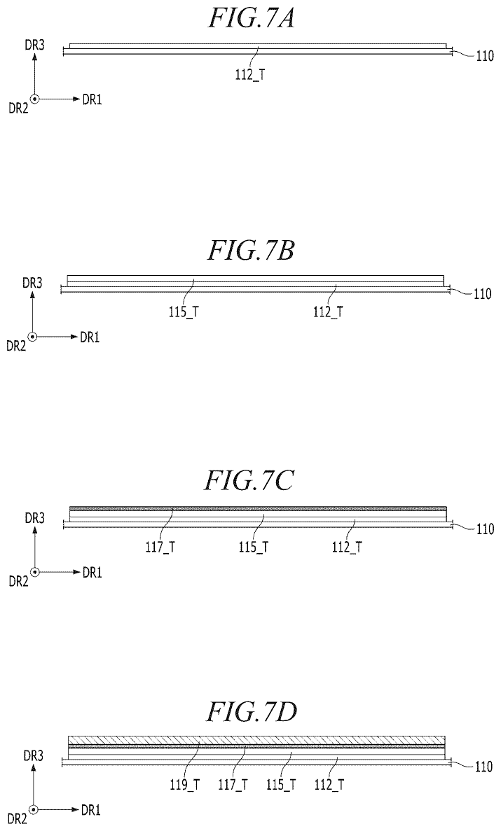

FIG. 5 is a cross-sectional view illustrating an ordinary circuit element layer. The circuit element layer 100 shown in FIG. 5 may be located on the substrate SUB. The circuit element layer 100 may correspond to the pixel circuit unit PXC shown in FIG. 2. The circuit element layer 100 may include a buffer layer 110, a semiconductor layer including a second active pattern 112, an oxygen rich region SUF, a first insulating layer 120, a first conductive layer including a second gate pattern 122, a second insulating layer 140, a second conductive layer including a third gate pattern 141, a third insulating layer 150, a third conductive layer including a second input pattern 163 and a second output pattern 164 (e.g., an input and output pattern), and a planarization layer 170.

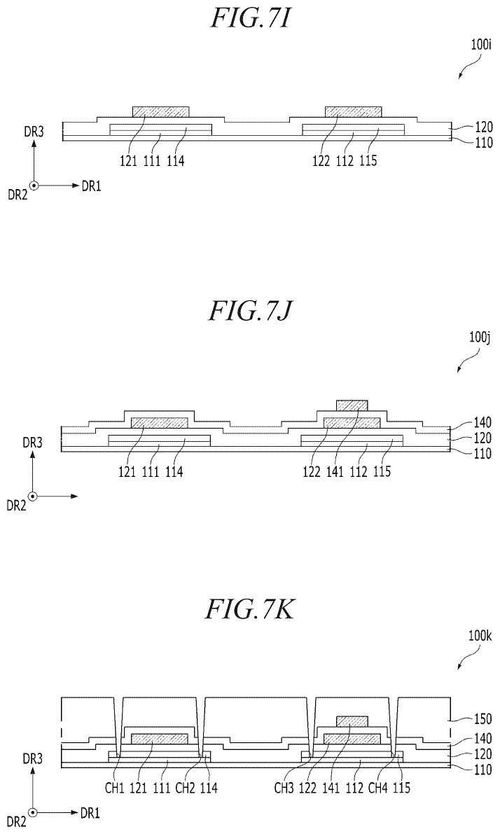

The semiconductor layer including the second active pattern 112 shown in FIG. 5 may include a polysilicon material. The active pattern having a desired shape may require a photoresistor pattern 119, which will be described with reference to FIG. 7F, on an upper surface of the semiconductor layer. However, there remains a problem that in the semiconductor layer including the second active pattern 112 formed of a polysilicon material, the photoresistor pattern 119 is not properly formed due to occurrence of reflection and scattering during an exposure process based on high reflectivity and protrusion.

To overcome the problem, a coating layer 117_T shown in FIG. 7C to be explained below may be required. The coating layer may be a Bottom Anti Reflection Coating amorphous carbon layer (BARC ACL). The BARC ACL may be a reflection protection coating layer applied below and mainly reduce interference phenomena and reflections to improve a pattern precision and uniformity.

The used ACL may be temporally used in a manufacturing process. The ACL is a thin film formed of amorphous carbon without a crystalline structure and is known for use in various technical applications due to its various electrical, physical, and chemical properties. As a fundamental property of ACL, penetration of moisture and oxygen may be effectively reduced or blocked, and electrical, optical, and physical properties may be adjustable through various methods. In addition, as a thickness and a density may be precisely adjusted, the ACL may be manufactured through a deposition.

However, a method of removal of ACL should be carefully chosen to reduce or minimize damage to quality of a process and substrate. A method of plasma etching may be preferred for a material, such as a display substrate, sensitive to heat or a chemical material.

Plasma etching for removal of ACL may commonly use oxygen plasma. This is to use reactive gas in plasma state to oxidize and remove carbon. That is, a carbon layer may be oxidized to become CO or CO₂, and may be removed.

That is, ACL may be applied to an upper surface of a semiconductor including a polysilicon material to reduce reflectivity. It can be confirmed that in case that ACL is added between a semiconductor layer and a photoresistor layer, reflectivity of a polysilicon material is reduced. Due to the reduced reflectivity, a photoresistor pattern 119 may be properly formed.

However, unlike the above advantages of ACL, an oxygen rich region SUF may be formed in an interface between a semiconductor layer and an insulating layer including silicon oxide on the semiconductor layer due to formation of an oxidized film on a surface of the semiconductor layer including polysilicon by oxygen plasma used for removal. Here, the oxygen rich region SUF refers to a region having a relatively higher oxygen content in or on a surface of a material than surroundings. Referring to FIG. 5, a precise position of the oxygen rich region SUF may be an interface between the semiconductor layer including the second active pattern 112 and the first insulating layer 120. In the oxygen rich region having sufficient oxygen, an electron structure may change, and electron conductivity may change. This may cause change of a property of a transistor by deteriorating quality of a transistor device.

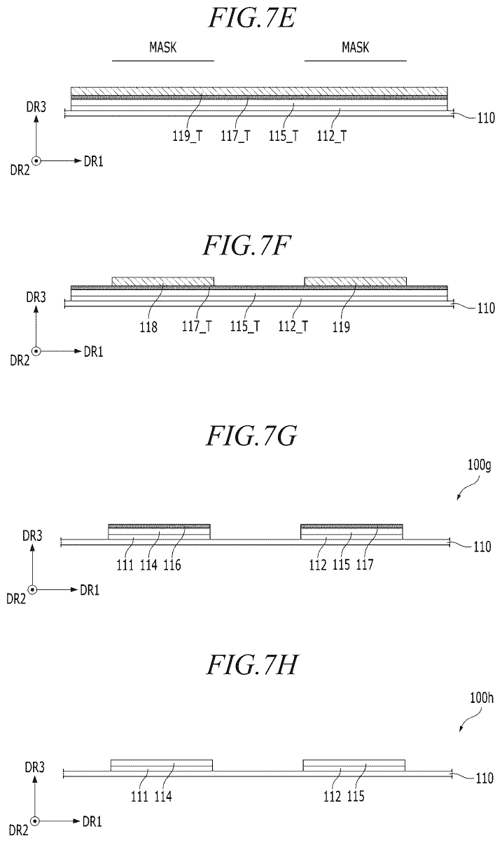

FIG. 6 is a cross-sectional view illustrating a circuit element layer according to one or more embodiments of the present disclosure. The circuit element layer 100 shown in FIG. 6 may be located on the substrate SUB. The circuit element layer 100 may correspond to the pixel circuit unit PXC shown in FIG. 2. The circuit element layer 100 may include a buffer layer 110, a semiconductor layer including an active pattern 112, a second additional insulating layer 115 (e.g., an additional insulating layer, in the claims), an oxygen rich region SUF, a first insulating layer 120, a first conductive layer including a gate pattern 112, a second conductive layer 140, a second conductive layer including a gate pattern 141, a third insulating layer 150, a third conductive layer including an input pattern 163 and an output pattern 164, and a planarization layer 170.

Among the elements shown in FIG. 6, elements other than the oxygen rich region SUF may correspond to elements shown in FIG. 5, and descriptions thereof are omitted. In comparison to FIG. 5, the circuit element layer 100 shown in FIG. 6 further includes the second additional insulating layer 115.

In comparison to FIG. 5, the described position of the oxygen rich region SUF may change. A position of the oxygen rich region SUF shown in FIG. 6 may be in an interface between the second additional insulating layer 115 and the first insulating layer 120.

The second additional insulating layer 115 may be inserted between the semiconductor layer including the second active pattern 112 and the first insulating layer 120. Therefore, in case that ACL is removed, direct introduction of oxygen to the semiconductor layer due to use of oxygen plasma may be reduced or prevented.

In case that the second additional insulating layer 115 is inserted, the oxygen rich region SUF may be formed between the second additional insulating layer 115 and the first insulating layer 120, instead of between the second active pattern 112 and the first insulating layer 120 as shown in FIG. 5. The above manufacturing process may reduce or prevent direct introduction of oxygen to the second active pattern 112 to maintain a device property of a transistor as it is.

FIGS. 7A through 7M are illustrations to explain a manufacturing method for a circuit element layer according to one or more embodiments of the present disclosure. The display device according to one or more embodiments of the present disclosure may be manufactured by having a circuit element layer formed on a substrate and a light-emitting element layer formed on the circuit element layer.

Referring to FIG. 7A, the operation of forming a circuit element layer 100 may include forming a buffer layer 110 on the substrate (as used herein, “on” may mean “above”). Here, forming a semiconductor layer 112_T is performed to form a channel on the first active pattern 111 and the second active pattern 112 on the buffer layer 110. A material of the semiconductor layer 112_T may be polysilicon.

Referring to FIG. 7B, the operation of forming a circuit element layer 100 may include forming an additional insulating layer 115_T on the semiconductor layer 112_T to form a channel on the first active pattern 111 and the second active pattern 112. As described for FIG. 6, the position of the oxygen rich region SUF may be in an interface of contacting a lower surface of ACL. In the oxygen rich region SUF, an electron structure may change, and electron conductivity may change. This may cause change in a property of a transistor by deteriorating quality of the transistor device. Accordingly, the additional insulating layer 115_T may be added to reduce or prevent direct contact with the semiconductor layer 112_T below ACL to reduce or prevent the above.

Referring to FIG. 7C, an operation of forming a circuit element layer 100 may include forming a coating layer 117_T including, for example, ACL on the additional insulating layer 115_T. As described for FIG. 5, ACL may be helpful in reducing reflectivity of the semiconductor layer 112_T including a material having high reflectivity. The reflectivity reduced by ACL may be helpful in precisely forming a photoresist pattern shown in FIG. 7D below. In addition, as shown in FIG. 7B, as the second additional insulating layer 115 may be inserted, a change in a property of a device by the oxygen rich region SUF even in case that ACL is removed may not be considered.

Referring to FIG. 7D, the operation of forming a circuit element layer 100 may include forming a photoresistor 119_T on the coating layer 117_T. The photoresistor is a material whose chemical property is changed upon exposure to light. The photoresistor is used to form a desired pattern layer through a photolithography process.

Referring to FIG. 7E, the operation of forming a circuit element layer 100 may include irradiating a light source to the photoresistor 119_T through a photolithography process using a mask MASK. Although it may vary depending on a photolithography process, in one or more embodiments, a wavelength of the used light source may be between 365 nanometers and 430 nanometers when a semiconductor layer of a polysilicon material is used. In addition, a shape of the used mask MASK may be for forming a shape of the first active pattern 111 and the second active pattern 112 shown in FIG. 4.

Referring to FIG. 7F, the operation of forming a circuit element layer 100 may include forming photoresistor patterns 118 and 119 by etching a photoresistor 119_T to a desired pattern using a mask MASK.

Referring to FIG. 7G, the operation of forming a circuit element layer (e.g., a circuit element layer precursor) 100g may include etching the semiconductor layer 112_T, the additional insulating layer 115_T, and the coating layer 117_T together at once using the etched photoresistor. The etched semiconductor layer 112_T may form the first active pattern 111 and the second active pattern 112, and the etched additional insulating layer 115_T may form the first additional insulating layer 114 and the second additional insulating layer 115. In addition, the etched coating layer 117_T may form the first coating layer 116 and the second coating layer 117.

An edge of the first active pattern 111 in the semiconductor layer, an edge of the first additional insulating layer 114, and an edge of the first coating layer 116 may all be aligned. In addition, an edge of the second active pattern 112 in the semiconductor layer, an edge of the second additional insulating layer 115, and an edge of the second coating layer 117 may all be aligned.

Referring to FIG. 7H, the operation of forming a circuit element layer (e.g., a circuit element layer precursor) 100h may include removing the first coating layer 116 and the second coating layer 117 using oxygen plasma. Through the operation, the first and second additional insulating layers 114 and 115 overlapping with the first and second active patterns 111 and 112 including a desired active pattern may be formed. As the first and second coating layers 116 and 117 is removed using oxygen plasma, an oxygen rich region SUF may be formed on the first and second additional insulating layers 114 and 115. By inserting the first and second additional insulating layers 114 and 115, direct formation of an oxygen rich region SUF on the first and second active patterns 111 and 112 may be reduced or prevented.

Referring to FIG. 7I, the operation of forming a circuit element layer (e.g., a circuit element layer precursor) 100i may include forming a first insulating layer 120 on the semiconductor layer, and forming a first conductive layer including a first gate pattern 121 and a second gate pattern 122. In the operation of forming a first insulating layer 120, an insulating layer including silicon oxide may be deposited.

In the operation of forming a first conductive layer, the first gate pattern 121 and the second gate pattern 122 may be patterned through etching. The first gate pattern 121 may overlap with the first active pattern 111, and the second gate pattern 122 may overlap with the second active pattern 112. In the operation of forming a first conductive layer, a gate line and a light-emission control line may be formed. Thereafter, doping may be performed to form a source region and a drain region of the first active pattern 111 and the second active pattern 112.

Referring to FIG. 7J, the operation of forming a circuit element layer (e.g., a circuit element layer precursor) 100j may include forming a second insulating layer 140 on the first insulating layer 120, and forming a second conductive layer including a third gate pattern 141 on the second insulating layer 140. In the operation of forming a second insulating layer 140, an insulating layer including silicon oxide or silicon nitride may be deposited.

In the operation of forming a second conductive layer, a third gate pattern 141 may be patterned through etching. The third gate pattern 141 may overlap with the second active pattern 112 and the second gate pattern 122. In the operation of forming a second conductive layer, a capacitor by the second gate pattern 122 and the third gate pattern 141 may be formed.

Referring to FIG. 7K, the operation of forming a circuit element layer (e.g., a circuit element layer precursor) 100k may include forming a third insulating layer 150 and forming contact holes CH1, CH2, CH3, and CH4. In the operation of forming a third insulating layer 150, an insulating layer including silicon oxide or silicon nitride may be deposited.

The contact holes CH1, CH2, CH3, and CH4 may be provided to form an input and output pattern (e.g., the first input pattern 161, the first output pattern 162, the second input pattern 163, and/or the second output pattern 164). The contact hole may be patterned to penetrate the first, second, and third insulating layers 120, 140, and 150 through etching.

Referring to FIG. 7L, the operation of forming a circuit element layer (e.g., a circuit element layer precursor) 100l may include forming a third conductive layer including a first input pattern 161, a first output pattern 162, a second input pattern 163, and a second output pattern 164. The third conductive layer including a first input pattern 161, a first output pattern 162, a second input pattern 163, and a second output pattern 164 may be located on the third insulating layer 150, and may contact the semiconductor layer through the contact holes CH1, CH2, CH3, and CH4. In one or more embodiments, the operation of forming a circuit element layer (e.g., a circuit element layer precursor) 100l may further include forming a planarization layer 170 thereafter.

FIG. 7M is a cross-sectional view of a circuit element layer according to one or more embodiments of the present disclosure. Referring to FIG. 7M, the circuit element layer 100m may include a buffer layer 110, a semiconductor layer including a first active pattern 111 and a second active pattern 112, a first additional insulating layer 114, a second additional insulating layer 115, a first insulating layer 120, a first conductive layer including a first gate pattern 121 and a second gate pattern 122, a second insulating layer 140, a second conductive layer including a third gate pattern 141, a third insulating layer 150, a third conductive layer including a first input pattern 161, a first output pattern 162, a second input pattern 163, and a second output pattern 164, and a planarization layer 170.

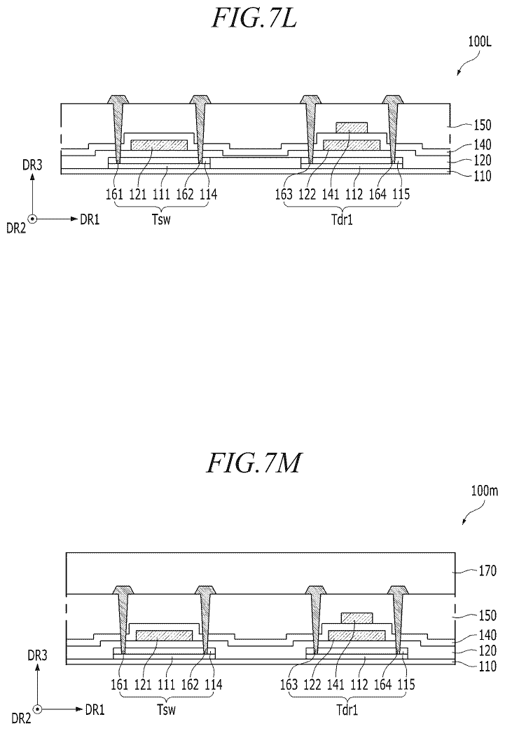

FIG. 8 is a cross-sectional view of a circuit element layer according to one or more embodiments of the present disclosure. In comparison of the circuit element layer 100_2 shown in FIG. 8 and the circuit element layer shown in FIG. 4, they are essentially the same except for that the circuit element layer 100_2 shown in FIG. 8 does not have a first additional insulating layer 114 and a second additional insulating layer 115 inserted, but does additionally have a third additional insulating layer 124 (e.g., another additional insulating layer, in the claims), a fourth additional insulating layer 125 (e.g., another additional insulating layer, in the claims), and a fifth additional insulating layer 145 added. Therefore, a detailed description of some of the elements shown in FIG. 8 is omitted or not repeated. The third additional insulating layer 124 may be located between the first gate pattern 121 and the third insulating layer 140. The fourth additional insulating layer 125 may be located between the second gate pattern 122 and the third insulating layer 140. In addition, the fifth additional insulating layer 145 may be located between the third gate pattern 141 and the third insulating layer 150. In this case, the first insulating layer 120, the second insulating layer 140, and the third insulating layer 150 may include silicon oxide.

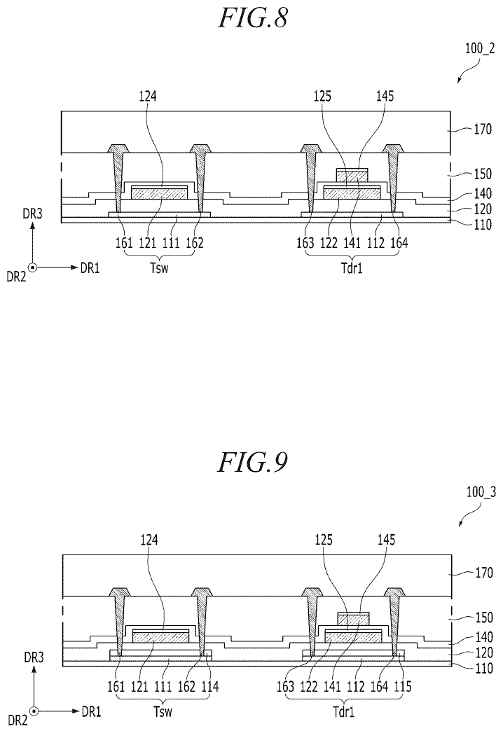

FIG. 9 is a cross-sectional view of a circuit element layer according to one or more embodiments of the present disclosure. In comparison of the circuit element layer 100_3 shown in FIG. 9 and the circuit element layer shown in FIG. 8, the circuit element layer 100_2 shown in FIG. 9 has a structure of having a first additional insulating layer 114 and a second additional insulating layer 115 added. Therefore, a detailed description of an element shown in FIG. 9 is omitted. A first additional insulating layer 114 may be located between the first active pattern 111 and the first insulating layer 120. A second additional insulating layer 115 may be located between the second active pattern 112 and the first insulating layer 120. In this case, the first insulating layer 120, the second insulating layer 140, and the third insulating layer 150 may include silicon oxide. That is, the circuit element layer 100_3 shown in FIG. 9 may have an additional insulating layer inserted on the semiconductor layer including the active pattern and an additional insulating layer also on the gate pattern to reduce or prevent direct introduction of oxygen to the active pattern and the gate pattern at the same time.

A display device according to one or more embodiments may be applicable to various electronic devices. An electronic device according to one or more embodiments may include the described display device and further include a module or a device having an additional function other than the display device.

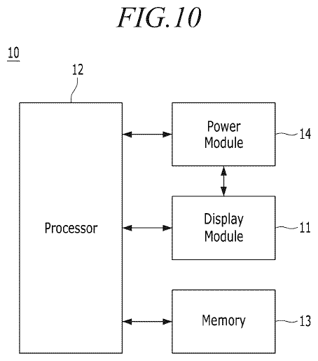

FIG. 10 is a block diagram of an electronic device according to one or more embodiments. Referring to FIG. 10, an electronic device 10 according to one or more embodiments may include a display module 11, a processor 12, a memory 13 and a power module 14.

The processor 12 may include at least one of a central processing unit (CPU), an application processor (AP), a graphic processing unit (GPU), a communication processor (CP), an image signal processor (ISP), or a controller.

In the memory 15, data information for operation of the processor 12 or the display module 11 may be stored. In case that the processor initiates an application stored in the memory 15, an image data signal and/or an input control signal may be transferred to the display module 11, and the display module 11 may be configured to process the received signal to provide an image information through a display screen.

The power module 14 may include a power supply module, such as a power adaptor or a battery device, and a power conversion module configured to generate power required for operation of an electronic device 10 by converting power supplied from the power supply module.

At least one of the elements of the electronic device 10 above may be included in a display device according to the embodiments described. In addition, a portion of separate modules functionally included in one module may be included in a display device, and another portion may be provided separately from the display device. For example, a display device may include a display module 11, and a processor 12, a memory 13, and a power module 14 may be provided as another device in an electronic device 10, other than the display device.

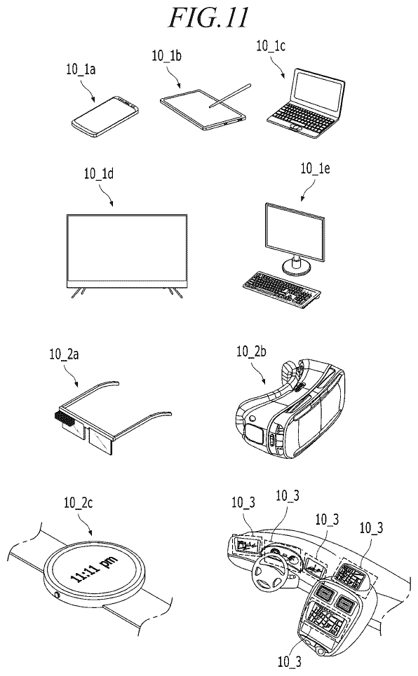

FIG. 11 are schematic diagrams of an electronic device according to various embodiments.

Referring to FIG. 11, various electronic devices applied with a display device according to embodiments may include not only an electronic device for displaying an image, such as a smartphone 10_A, a tablet 10_1B, a laptop 10_1C, a TV 10_1D, and/or a desktop monitor 10_1E, a wearable electronic device including a display module, such as smart glasses 10_2A, a head-mounted display 10_2B, a smartwatch 10_2C, and/or an electronic device for a vehicle including a display module, such as a dashboard, center fascia, a Center Information Display (CID) on a dashboard, and/or a room mirror display of a vehicle.

While certain embodiments of the present disclosure have been described above, anyone ordinarily skilled in the art to which the present disclosure pertains shall appreciate that there may be a variety of modifications and permutations of the present disclosure without departing from the technical ideas and scopes of the present disclosure that are defined in the appended claims. Moreover, it shall be appreciated that the disclosed embodiments are not intended to restrict the present disclosure thereto and that every technical idea within the appended claims and their equivalents is interpreted to be included in the scope of the present disclosure.

What is claimed is:

1. A display device comprising:
a substrate;
a light-emitting element layer above the substrate, and comprising a light-emitting material; and
a circuit element layer between the substrate and the light-emitting element layer, and comprising:
a semiconductor layer above the substrate, and comprising an active pattern;
a first conductive layer above the semiconductor layer, and comprising a first gate pattern overlapping the active pattern;
a first insulating layer between the semiconductor layer and the first conductive layer;
a second insulating layer above the first insulating layer and the first conductive layer;
a third conductive layer above the semiconductor layer and the second insulating layer, and comprising an input and output pattern penetrating the first insulating layer and the second insulating layer to contact the active pattern; and
an additional insulating layer between the active pattern and the first insulating layer, and contacting the first insulating layer,
wherein an interface between the first insulating layer and the additional insulating layer has an oxygen content that is greater than that of the first insulating layer.

2. The display device of claim 1, wherein an edge of the additional insulating layer and an edge of the semiconductor layer are aligned.

3. The display device of claim 1, wherein the semiconductor layer comprises polysilicon.

4. The display device of claim 1, wherein the additional insulating layer comprises a same material as the first insulating layer.

5. The display device of claim 1, wherein the first insulating layer and the additional insulating layer comprise silicon oxide.

6. The display device of claim 1, wherein the second insulating layer comprise silicon nitride.

7. The display device of claim 1, wherein the circuit element layer further comprises another additional insulating layer between the first gate pattern and the second insulating layer, and contacting the second insulating layer, and
wherein an interface between the second insulating layer and the another additional insulating layer has an oxygen content that is greater than that of the another additional insulating layer.

8. The display device of claim 7, wherein an edge of the another additional insulating layer and an edge of the first gate pattern are aligned.

9. The display device of claim 7, wherein the another additional insulating layer comprises a same material as the second insulating layer.

10. The display device of claim 7, wherein the second insulating layer and the another additional insulating layer comprises silicon oxide.

11. The display device of claim 7, wherein the circuit element layer further comprises:
a second conductive layer above the second insulating layer, and comprising a third gate pattern;
a third insulating layer above the second insulating layer and the third conductive layer; and
a fifth additional insulating layer between the third gate pattern and the third insulating layer and contacting the third insulating layer, and
wherein an interface between the third insulating layer and the fifth additional insulating layer has an oxygen content that is greater than that of the fifth additional insulating layer.

12. The display device of claim 11, wherein an edge of the fifth additional insulating layer and an edge of the third gate pattern are aligned.

13. The display device of claim 11, wherein the third insulating layer and the fifth additional insulating layer comprise silicon oxide.

14. A manufacturing method for a display device, the method comprising:
forming a semiconductor layer comprising an active pattern corresponding to a transistor above a substrate by:
forming an additional insulating layer above the semiconductor layer forming a coating layer above the additional insulating layer;
etching the semiconductor layer, the additional insulating layer, and the coating layer to form the active pattern; and
removing the coating layer;
forming a first insulating layer above the semiconductor layer;
forming a first conductive layer comprising a gate pattern above the first insulating layer and overlapping the active pattern;
forming a second insulating layer above the first insulating layer and the first conductive layer; and
forming a third conductive layer comprising an input and output pattern penetrating the first insulating layer and the second insulating layer to contact the active pattern.

15. The method of claim 14, wherein the removing the coating layer comprises supplying oxygen gas to remove the coating layer.

16. The method of claim 14, wherein the coating layer comprises amorphous carbon.

17. The method of claim 14, wherein the forming the active pattern further comprises:
applying a photoresistor; and
etching the photoresistor with a mask patterned to have a shape corresponding to the active pattern.

18. The method of claim 14, wherein the forming the first conductive layer further comprises:
forming another additional insulating layer above the gate pattern;
forming another coating layer above the another additional insulating layer;
etching the first conductive layer, the another additional insulating layer, and the another coating layer to form the gate pattern; and
removing the another coating layer.

19. An electronic device comprising:
a display device for outputting image information;
a processor configured to control the display device;
a memory configured to store data for operation of the display device or the processor; and
a power conversion module configured to generate or supply power,
wherein the display device comprises:
a substrate;
a light-emitting element layer above the substrate, and comprising a light-emitting material; and
a circuit element layer between the substrate and the light-emitting element layer, and comprising:
a semiconductor layer above the substrate, and comprising an active pattern;
a first conductive layer above the semiconductor layer, and comprising a gate pattern overlapping the active pattern;
a first insulating layer between the semiconductor layer and the first conductive layer;
a second insulating layer above the first insulating layer and the first conductive layer;
a third conductive layer above the semiconductor layer and the second insulating layer, and comprising an input and output pattern penetrating the first insulating layer and the second insulating layer to contact the active pattern; and
an additional insulating layer between the active pattern and the first insulating layer, and contacting the first insulating layer, and
wherein an interface between the first insulating layer and the additional insulating layer has an oxygen content that is greater than that of the first insulating layer.

20. The electronic device of claim 19, wherein an edge of the additional insulating layer and an edge of the semiconductor layer are aligned to have a same pattern in plan view.
